(19) United States
(12) Patent Application Publication
(10) Pub. No.: US 2012/0178265 A1
(43) Pub. Date: Jul. 12, 2012

(54) METHOD OF MANUFACTURING SEMICONDUCTOR DEVICE USING SOD METHOD

(75) Inventor: Jiro MIYAHARA, Tokyo (JP)

(73) Assignee: ELPIDA MEMORY, INC., Tokyo (JP)

(21) Appl. No.: 13/341,449

(22) Filed: Dec. 30, 2011

(30) Foreign Application Priority Data
Jan. 6, 2011 (JP) 2011-001305

(51) Int. Cl. H01L 21/31

(52) U.S. Cl. 438/782; 257/E21.24

(57) ABSTRACT

Such a method is disclosed that includes forming a liner film to cover a surface of the substrate including a trench, washing a surface of the liner film with water, removing remaining water after the washing, applying a polysilazane solution to fill the trench by spin coating after the removing, and reforming the polysilazane solution into a silicon oxide film by annealing.

### BACKGROUND OF THE INVENTION

1. Field of the Invention

The present invention relates to a method of manufacturing a semiconductor device, and particularly to a method of manufacturing a semiconductor device in which an insulating film, which fills a micro-trench, is formed by SOD (Spin On Dielectric) method.

2. Description of Related Art

In manufacturing a semiconductor device, the following and other methods have been used to form an insulating film in a STI (Shallow Trench Isolation) trench, an area between gate electrodes, an area between bit lines, or any other extremely narrow area: a HDP-CVD (High Density Plasma-Chemical Vapor Deposition) method, and a method of reflowing after BPSG (Boron Phosphorus Silicon Glass) is deposited.

However, each of the above areas has become narrower in width as elements become more microscopic. With the above methods, it is becoming increasingly difficult to embed an insulating film sufficiently. In recent years, research has been going on about the SOD method, by which a polysilazane solution that is good at being embedded is embedded by spin coating, and the polysilazane is then reformed into a silicon oxide film by annealing in a steam (H₂O) atmosphere (See Japanese Patent Application Laid-Open No. 2010-166026).

According to the SOD method, before a film of the polysilazane solution is formed by spin coating, a liner film having residence to oxidation is formed across an entire surface of a substrate, thereby preventing a lower-layer film from being oxidized by annealing in the reforming process. For the liner film, a SiON film is preferably used as disclosed in Japanese Patent Application Laid-Open No. 2010-166026.

However, it has been found that the formation of the SiON film on the surface of the substrate causes a sublimate of ammonia as a foreign substance. It is possible to remove the sublimate of ammonia by performing scrubber water washing. However, it has been found that, with scrubber water washing, a new problem arises that voids emerge in the finally formed silicon oxide film. Such voids have been confirmed by electron microscope observation. Because such voids could be a cause of malfunctioning of a device, the occurrence of voids needs to be inhibited.

### SUMMARY

In one embodiment, there is provided a method of manufacturing a semiconductor device having a substrate that includes: forming a liner film to cover a surface of the substrate including a trench; washing a surface of the liner film with water; removing remaining water after the washing; applying a polysilazane solution to fill the trench by spin coating after the removing; and reforming the polysilazane solution into a silicon oxide film by annealing.

In another embodiment, there is provided a method of manufacturing a semiconductor device that includes: pre-baking a substrate; coating a polysilazane solution on the substrate after the pre-baking; and post-baking the substrate after coating so that the polysilazane solution is reformed into a silicon oxide film.

### BRIEF DESCRIPTION OF THE DRAWINGS

FIGS. 1A to 1H are diagrams indicative of an embodiment of processes of manufacturing a semiconductor device;

FIG. 2A is a flowchart indicative of an embodiment of the processes from water removal through reforming in the manufacturing processes;

FIG. 2B is a flowchart indicative of prototype processes in the course of making the present invention;

FIG. 3 is a diagram indicative of an embodiment of a time sequence of the process in which the polysilazane solution is applied; and

FIG. 4 is a graph indicative of an embodiment of experimental data in the form of a cumulative bar chart.

### DETAILED DESCRIPTION OF THE EMBODIMENTS

Preferred embodiments of the present invention will be explained below in detail with reference to the accompanying drawings.

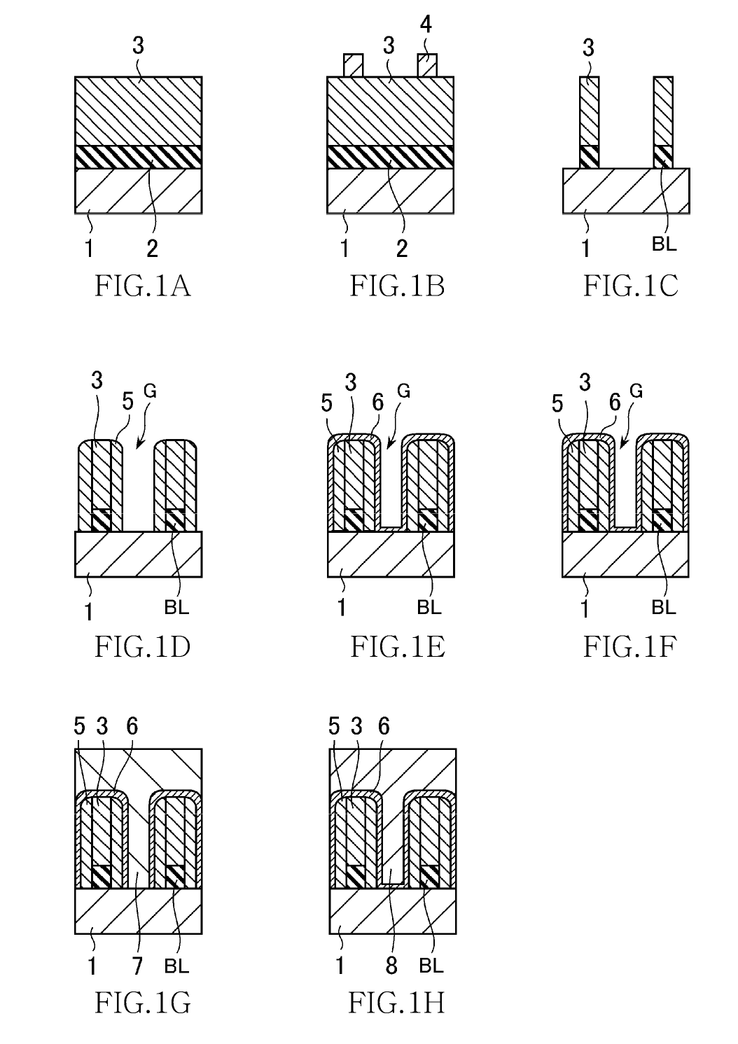

Referring now to FIGS. 1A to 1H, a semiconductor device shown in the diagrams is a semiconductor memory device such as DRAM (Dynamic Random Access Memory), for example, and includes a plurality of bit lines BL that run parallel to each other. In between the bit lines BL, trench regions G, which are extremely narrow in width, are formed. According to the manufacturing processes of the present embodiment, a silicon oxide film 8 shown in FIG. 1H is eventually formed inside the trench regions G.

The manufacturing processes of the present embodiment include the following processes, which are carried out in the following order: a process of forming bit lines BL and sidewall insulating films 5 (FIGS. 1A to 1D); a process of forming a liner film 6 (FIG. 1E); a scrubber water washing process (FIG. 1F); a water removal process and a process of applying a polysilazane solution (FIG. 1G); and a process of reforming the polysilazane solution (FIG. 1H). A main feature of the manufacturing processes of the present embodiment is that, between the scrubber water washing process and the process of applying the polysilazane solution, a water removal process is provided to remove remaining water after water washing. Therefore, the remaining water after water washing is removed before the process of applying the polysilazane solution. As a result, it is possible to keep voids from emerging in the finally formed silicon oxide film 8. The following describes each of the processes in detail.

First, as shown in FIG. 1A, on a surface of a wafer not shown in the diagram (which is a substrate before being divided into individual chips), an interlayer insulating film 1 made of a silicon oxide film is formed. On the interlayer insulating film 1, a wiring film 2, which is a material of bit lines BL, and a mask insulating film 3, which is made of a silicon nitride film, are stacked in that order. For the wiring film 2, a metallic film made of a laminated film of tungsten nitride and tungsten is preferably used, for example.

Then, to an upper surface of the mask insulating film 3, a resist 4 is applied, and patterning is performed on the basis of a pattern of bit lines BL as shown in FIG. 1B. Etching is sequentially performed on the silicon nitride film and the metallic film with the use of dry etching. Therefore, patterning is performed on the wiring film 2 so as to produce the shape of bit lines BL as shown in FIG. 1C. The pitch between the bit lines BL is for example 110 nm.

Then, a silicon nitride film is formed across an entire surface of the wafer. As for the amount of the film formed at the time, it is preferred that the lateral-direction film thickness be about 25 nm. After the silicon nitride film is formed, etch-back is subsequently performed with the use of dry etching. After etch-back is completed, as shown in FIG. 1D, the sides of the bit lines BL and mask insulating films 3 are covered with sidewall insulating films 5, and the interlayer insulating film 1 is exposed in a region between the bit lines BL. The above processes produce a trench region G between the bit lines BL, which is about 40 nm in width and about 260 nm in depth.

Then, as shown in FIG. 1E, a liner film 6 is formed so as to cover an entire surface of the wafer (which is a process of forming the liner film). The reason the liner film 6 is provided is to ensure that the interlayer insulating film 1 and the sidewall insulating films 5 are not tainted in a process of diffusing polysilazane, which is described below. Specifically, it is preferred that a SiON film be used as the liner film 6. The SiON film containing more oxygen is preferred to the SiON film containing nitrogen. More specifically, the atomic ratio of oxygen atoms to nitrogen atoms is preferably 2.2 to 5.5, or more preferably 2.8 to 3.5. Moreover, the amount of nitrogen atoms contained in the liner film 6 is preferably 10 to 20 atom %, or more preferably 14 to 17 atom %. Incidentally, if the amount of nitrogen atoms contained in the liner film 6 is less than 10 atom %, and the atomic ratio of oxygen atoms to nitrogen atoms is greater than 5.5, the capability of the liner film 6 to inhibit oxide-film diffusion decreases, making it difficult to prevent the metallic films and the silicon oxide films beneath the liner film 6 from being oxidized. If the amount of nitrogen atoms contained in the liner film 6 is greater than 20 atom %, and the atomic ratio of oxygen atoms to nitrogen atoms is less than 2.2, the polysilazane formed in the trench region G is not reformed sufficiently, resulting in voids in the silicon oxide film 8.

It is preferred that the liner film 6 be formed by, for example, LPCVD (Low Pressure Chemical Vapor Deposition) method. In this case, as a reactant gas, a mixed gas of dichlorosilane (SiH₂Cl₂), ammonia (NH₃) and nitrous oxide (N₂O) is preferably used. By changing the gas mix proportion of ammonia to nitrous oxide, it is possible to change the composition ratio of the liner film 6. Therefore, it is possible to set the atomic ratio of oxygen atoms to nitrogen atoms in the liner film 6 and the amount of nitrogen atoms contained in the liner film 6 within the above ranges by controlling the amounts of the gases in such a way. As a specific example, under the following conditions, a suitable liner film 6 can be formed: the flow rate of dichlorosilane is 140 sccm, the flow rate of ammonia is 10 sccm, the flow rate of nitrous oxide is 500 sccm, the pressure of a film-formation atmosphere is 238 Pa, and a film-formation temperature is 630 degrees Celsius. Incidentally, as for the above three types of gas, it is desirable that nitrous oxide, ammonia and dichlorosilane be introduced into a reaction chamber in that order, rather than being supplied simultaneously. The advantage is that it is easy to control the composition of the liner film 6 from the initial stage of film formation. The liner film 6 formed under the above conditions contains 16 atom % of nitrogen atoms, and the atomic ratio of oxygen atoms to nitrogen atoms is 3.0.

The liner film 6 may be a single-layer film of a SiON film. Alternatively, a silicon oxide film that is 2 to 5 nm in thickness may be formed below the SiON film.

Then, as shown in FIG. 1F, the entire wafer is washed with water (Water-washing process). The water washing process is aimed at removing a sublimate of ammonia, which emerges when the liner film 6 is formed. It is preferred that a scrubber washing machine be used in water washing (scrubber water washing).

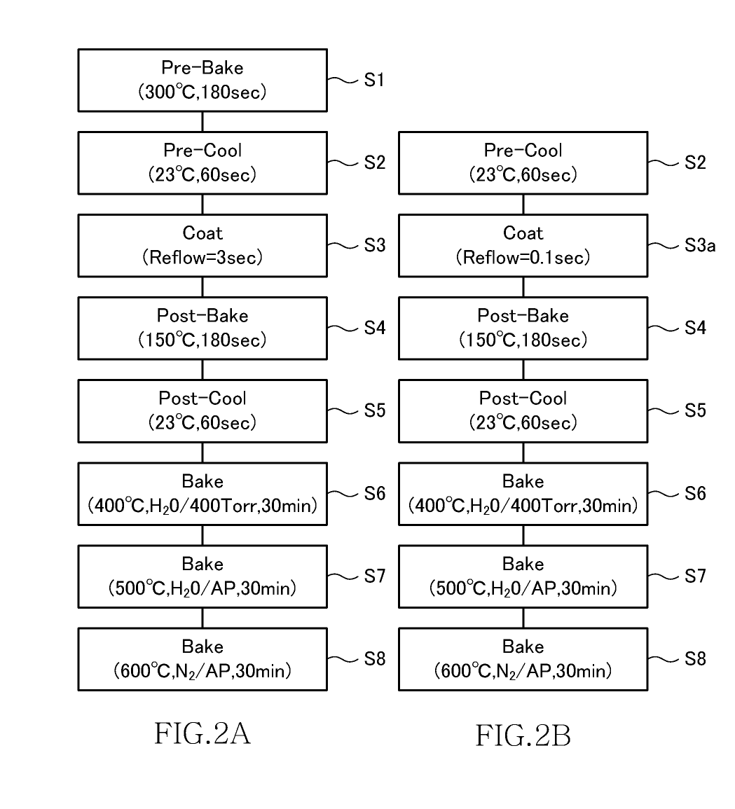

Then, the remaining water is removed from a surface of the liner film 6 after water washing (Water removal process). After that, a polysilazane solution is applied so that the surface of the wafer is covered with polysilazane 7 as shown in FIG. 1G (Application process). After the application process is completed, as shown in FIG. 1H, the polysilazane 7 is reformed into a silicon oxide film 8 (Reforming process). The following describes in detail the water removal process, the application process and the reforming process with reference to FIG. 2.

Turning to FIGS. 2A and 2B, the application process of the polysilazane solution is carried out with a SOD applicator (not shown) equipped with a hot plate. In the polysilazane solution application process in the manufacturing processes of the present embodiment, as shown in FIG. 2A, first a process of heating a wafer (pre-baking) is performed (Step S1). The heating process corresponds to the water removal process, in which the remaining water is removed following scrubber water washing. As shown in FIG. 2B, in the prototype processes, the heating process of the above step S1 is not performed.

Specifically, the water removal process uses the hot plate of the SOD applicator to heat the wafer, thereby vaporizing the remaining water. It is preferred that the heating temperature be 300 degrees Celsius, and the heating time 180 seconds. In this manner, the remaining water is sufficiently removed, leading to an improvement in the wettability of the surface of the liner film 6. Therefore, when the polysilazane solution is applied later, the occurrence of voids can be inhibited, as again described below in detail with reference to experimental data.

Then, a process of cooling the wafer (pre-cooling) is performed (Cooling process at step S2). It is preferred that the cooling process takes place with the wafer being placed in an atmosphere with a temperature of 23 degrees Celsius for 60 seconds. After the cooling process is completed, the polysilazane solution is applied (Step S3). The processes of steps S2 and S3 are performed even in the prototype processes as shown in FIG. 2B. However, the present embodiment is different from the prototype processes in terms of the duration in which a reflow process (described below), which is part of the process of step S3, continues. The difference will be described in detail below.

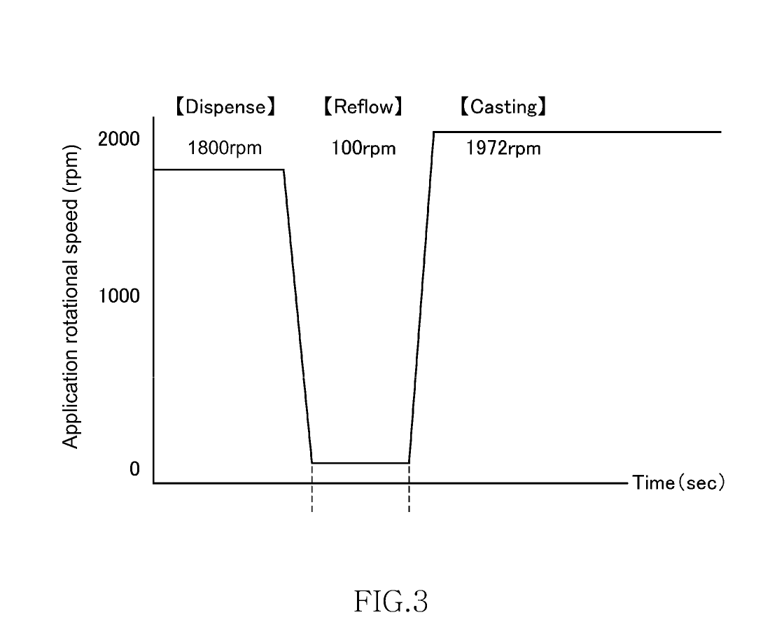

Turning to FIG. 3, in the diagram, the horizontal axis represents time, and the vertical axis represents an application rotational speed (rpm). As shown in the diagram, the process of applying the polysilazane solution consists of three processes: a dispense process, in which drops of polysilazane solution are put onto the surface of the wafer; a reflow process, in which the polysilazane solution, which is put onto the wafer surface in drops during the dispense process, is diffused; and a casting process, in which the polysilazane solution is removed after the reflow process. Incidentally, in the dispense process, drops of polysilazane solution are put onto a central portion of the wafer surface. In the reflow process, the polysilazane solution, which is put onto the wafer surface in drops during the dispense process, is diffused so as to spread to region from the center to the edge of the wafer. In the casting process, the wafer is rotated at high speed, thereby shaking the residual polysilazane solution off the wafer surface.

The above three processes are all performed with the wafer being rotated. However, the preferred rotational speeds of the above three processes are different from each other as shown in FIG. 3. Specifically, it is preferred that the rotational speed (second rotational speed) of the reflow process be set lower than the rotational speed (first rotational speed) of the dispense process and the rotational speed (third rotational speed) of the casting process. The above rotational speeds are so determined that the polysilazane solution can be evenly spread across the entire wafer.

Preferred specific speeds are listed as follows: the second rotational speed is 200 rpm or less, and the first and third rotational speeds are 1,000 rpm or more. More preferably, the first, second and third rotational speeds are 1,800 rpm, 100 rpm and 1,972 rpm, respectively, as shown in FIG. 3.

The present embodiment is different from the prototype processes in terms of the duration in which the reflow process continues, as shown in FIG. 2. That is, according to the present embodiment, the duration of the reflow process is 3 seconds. However, in the prototype processes, the duration is 0.1 second as shown in FIG. 2B. It is preferred that the duration of the reflow process be set at 3 seconds or more in order to inhibit the occurrence of voids by enabling the polysilazane solution to spread sufficiently into the inside of the trench region G. The advantage will be described again in detail below with reference to experimental data.

Returning to FIG. 2, after the application of the polysilazane solution is completed, the process of heating the wafer (post-baking) is performed again so as to evaporate the residual polysilazane solution (Heating process at step S4). Specifically, the hot plate of the SOD applicator, which is used at step S1, is used to heat the wafer in an air atmosphere. It is preferred that the heating temperature be 150 degrees Celsius, and the heating time 180 seconds.

Next, a process of cooling the wafer (post-cooling) is performed again (Step S5). It is preferred that the cooling process takes place under the same conditions as at step S2, i.e. the wafer is placed in an atmosphere with a temperature of 23 degrees Celsius for 60 seconds.

Next, processes of heating the wafer are performed in three stages. The process consisting of these heating processes is the so-called annealing, and is equivalent to the process of reforming the polysilazane solution into a silicon oxide film. Specifically, first of all, the wafer is heated at 400 degrees Celsius for 30 minutes in an 400 Torr steam (H₂O) atmosphere (Step S6). Next, while maintaining the steam (H₂O) atmosphere, the pressure in a furnace is increased to an atmospheric pressure and the heating temperature is raised to 500 degrees Celsius. Under such a condition, the wafer is further heated for 30 minutes (Step S7). Subsequently, the atmosphere gas is changed to nitrogen gas (N₂), and the wafer is further heated at 600 degrees Celsius for 30 minutes in an non-oxidizing atmosphere under an atmospheric pressure (Step S8).

After the above-described processes are each carried out, a semiconductor device is completed with the silicon oxide film 8 embedded inside the trench region G as shown in FIG. 1H. As described above, the water removal process in which the remaining water is removed after water washing is provided before the application process of the polysilazane solution; the duration of the reflow process is set at 3 seconds or more. Therefore, the completed semiconductor device has far fewer voids in the silicon oxide film 8.

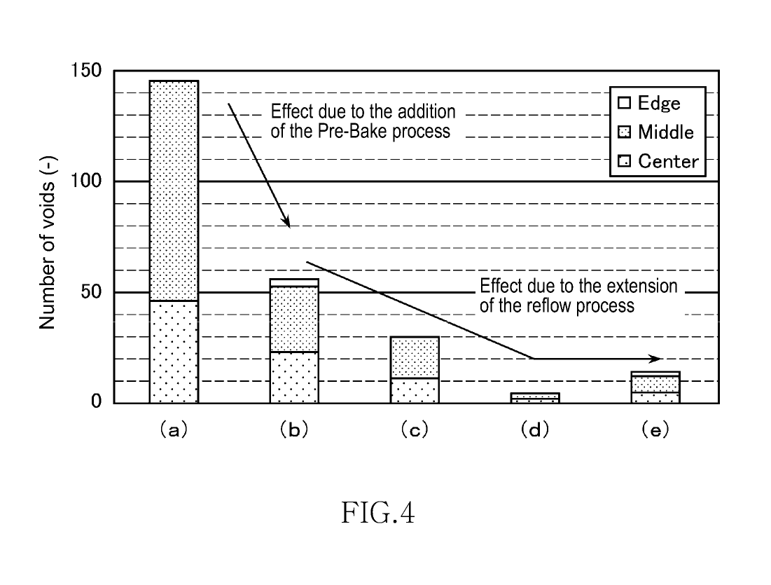

Turning to FIG. 4, the experimental data show the results of counting voids in the silicon oxide film 8 after the above-described processes were all completed. The wafer was cut around the center of the trench region G, and the cross-sectional surface thereof was examined with an electron microscope to count the voids. In the diagram, “Edge,” “Middle,” and “Center” indicate the results of counting on the edge portion's cross-sectional surface, intermediate region's cross-sectional surface, and central portion's cross-sectional surface, respectively, on the wafer surface. Moreover, (a) shows the results of counting in a semiconductor device produced in the prototype processes. (b) to (e) show the results of counting for 0.1 second, 1 second, 3 seconds and 5 seconds in reflow-process duration, respectively, in the semiconductor device produced according to the present embodiment.

As shown in FIG. 4, compared with the semiconductor device produced in the prototype processes, the number of voids appearing in the silicon oxide film 8 of the semiconductor device produced according to the present embodiment was smaller in any of the examples shown in (b) to (e). As made clear by a comparison between (a) and (b), firstly, providing the water removal process prior to the polysilazane solution application process is effective in reducing the number of voids by half or more.

It is clear from (b) to (e) that, at least within the period of 0.1 to 3 seconds, the longer the duration of the reflow process, the more the voids decrease in number. Incidentally, in the case of (e), the number of voids increased compared with the example of (d). However, the increase may be attributable to measurement error. Actually, any significant increase or decrease in the number of voids did not occur when the reflow-process duration was 3 seconds or more.

Based on the results shown in FIG. 4, it can be said that providing the water removal process prior to the polysilazane solution application process, as well as setting the reflow-process duration to 3 seconds or more, helps to significantly reduce the number of voids appearing in the silicon oxide film 8.

As described above, according to the semiconductor device manufacturing processes of the present embodiment, it is possible to keep voids from appearing in the silicon oxide film formed by the SOD method.

Since the newly provided water removal process makes use of the hot plate that is also used in the heating process performed just after the application process, the water removal process and the heating process can be performed by a single SOD applicator. Therefore, according to the semiconductor device manufacturing processes of the present embodiment, it is possible to extremely reduce an impact of the additional water removal process on actual manufacturing sites.

It is apparent that the present invention is not limited to the above embodiments, but may be modified and changed without departing from the scope and spirit of the invention.

For example, according to the above embodiment, the present invention is applied to the silicon oxide film 8, which fills the trench region G between the bit lines BL. However, the scope of application of the present invention is not limited to the above. That is, the present invention can be widely applied to various processes in which a silicon oxide film is embedded in a trench-like narrow area.

What is claimed is:

1. A method of manufacturing a semiconductor device having a substrate, comprising:
forming a liner film to cover a surface of the substrate including a trench;
washing a surface of the liner film with water;
removing remaining water after the washing;
applying a polysilazane solution to fill the trench by spin coating after the removing; and
reforming the polysilazane solution into a silicon oxide film by annealing.

2. The method of manufacturing the semiconductor device as claimed in claim 1, wherein the removing is performed by heating the substrate to vaporize the remaining water.

3. The method of manufacturing the semiconductor device as claimed in claim 2, further comprising heating the substrate after the applying and before the reforming,
wherein the substrate is heated by a common hot plate in the removing and the heating after the applying and before the reforming.

4. The method of manufacturing the semiconductor device as claimed in claim 3, wherein, in the removing, the substrate is heated at a higher temperature than in the heating after the applying and before the reforming.

5. The method of manufacturing the semiconductor device as claimed in claim 1, further comprising cooling the substrate after the removing and before the applying.

6. The method of manufacturing the semiconductor device as claimed in claim 1, wherein
the applying includes:
dropping the polysilazane solution on the surface of the substrate;
diffusing the polysilazane solution to the surface of the substrate; and
removing the polysilazane solution after the diffusing, and
the diffusing is performed at least 3 seconds.

7. The method of manufacturing the semiconductor device as claimed in claim 6, wherein
the dropping is performed while rotating the substrate at a first rotational speed,
the diffusing is performed while rotating the substrate at a second rotational speed,
the removing the polysilazane solution is performed while rotating the substrate at a third rotational speed, and
the second rotational speed is slower than the first and third rotational speeds.

8. The method of manufacturing the semiconductor device as claimed in claim 7, wherein the second rotational speed is 200 rpm or less, and the first and third rotational speeds are 1,000 rpm or more.

9. A method of manufacturing a semiconductor device comprising:
pre-baking a substrate;
coating a polysilazane solution on the substrate after the pre-baking; and
post-baking the substrate after coating so as to evaporate a residual polysilazane solution.

10. The method of manufacturing the semiconductor device as claimed in claim 9, further comprising:
forming a liner film on the substrate; and
washing the liner film before the pre-baking.

11. The method of manufacturing the semiconductor device as claimed in claim 9, wherein the pre-baking is performed at higher temperature than the post-baking.

12. The method of manufacturing the semiconductor device as claimed in claim 9, wherein the coating includes:
dropping the polysilazane solution on the substrate while rotating the substrate at a first rotational speed;
diffusing the polysilazane solution to the substrate after dropping while rotating the substrate at a second rotational speed slower than the first rotational speed; and
removing a part of the polysilazane solution after the diffusing while rotating the substrate at a third rotational speed faster than the second rotational speed.

13. The method of manufacturing the semiconductor device as claimed in claim 12, wherein the diffusing is performed at least 3 seconds.

14. The method of manufacturing the semiconductor device as claimed in claim 9, further comprising reforming the polysilazane solution into a silicon oxide film by annealing after the post-baking.
